(19) United States
(12) Patent Application Publication
(10) Pub. No.: US 2026/0136506 A1
(43) Pub. Date: May 14, 2026

(54) STORAGE DEVICE

(71) Applicant: SAMSUNG ELECTRONICS CO., LTD., Suwon-si (KR)

(72) Inventors: Heechul LEE, Suwon-si (KR); Bumjun KIM, Suwon-si (KR); Jaebeom BYUN, Suwon-si (KR); Jungmoo SON, Suwon-si (KR); Kitaek LEE, Suwon-si (KR)

(73) Assignee: SAMSUNG ELECTRONICS CO., LTD., Suwon-si (KR)

(21) Appl. No.: 19/217,798

(22) Filed: May 23, 2025

(30) Foreign Application Priority Data
Nov. 14, 2024 (KR) 10-2024-0162468

(51) Int. Cl. H05K 7/20; H05K 7/14

(52) U.S. Cl. CPC H05K 7/20709; H05K 7/1487

(57) ABSTRACT

A storage device includes a printed circuit board including an interface configured to be coupled to an external host, a controller on the printed circuit board, at least one memory device on the printed circuit board, and configured to store data in response to control of the controller, and a case having an internal space accommodating the printed circuit board, the controller, and the at least one memory device and externally exposing the interface, where the case includes a first surface and a second surface facing each other, and a third surface and a fourth surface facing each other and extending from edges of the first surface and the second surface, and a plurality of structures on at least one of the first surface and the second surface, the plurality of structures configured to generate air turbulence.

### CROSS-REFERENCE TO RELATED APPLICATION(S)

This application is based on and claims priority to Korean Patent Application No. 10-2024-0162468, filed on Nov. 14, 2024 in the Korean Intellectual Property Office, the disclosure of which is incorporated by reference herein in its entirety.

### BACKGROUND

The present disclosure relates to a storage device which may have improved heat dissipation performance.

A server for providing various services may have a plurality of storage devices externally connected thereto, and the storage device may be implemented as a Solid State Drive (SSD) device, or the like. The storage device may operate by exchanging data with a server, and during the operation, heat may be generated not only in the server but also in the storage device. As the temperature increases due to the heat generated by the server and the storage device, operating performance of the server as well as the storage device may deteriorate and power consumption of the server may also increase. To improve the heat dissipation performance of storage device, a method such as attaching a heat sink to the storage device has been proposed. However, a volume of the heat sink may reduce the number of storage devices that may be connected to the server, which may cause problems in operating the server inefficiently.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a storage device that may improve heat dissipation performance by providing a turbulator which generates an air vortex around the storage device.

Additional aspects will be set forth in part in the description which follows and, in part, will be apparent from the description, or may be learned by practice of the presented embodiments.

According to an aspect of an example embodiment, a storage device may include a printed circuit board including an interface configured to be coupled to an external host, a controller on the printed circuit board, at least one memory device on the printed circuit board, and configured to store data in response to control of the controller, and a case having an internal space accommodating the printed circuit board, the controller, and the at least one memory device and externally exposing the interface, where the case includes a first surface and a second surface facing each other, and a third surface and a fourth surface facing each other and extending from edges of the first surface and the second surface, and a plurality of structures on at least one of the first surface and the second surface, the plurality of structures configured to generate air turbulence.

According to an aspect of an example embodiment, a storage device may include a printed circuit board comprising an upper surface on which a controller and at least one memory device are provided, and an interface configured to be coupled to a host, and a case having an internal space accommodating the printed circuit board, the case comprising a first surface and a second surface that are parallel to the upper surface of the printed circuit board, where at least one of the first surface and the second surface comprises a plurality of turbulators.

According to an aspect of the disclosure, a storage device may include a case having an internal space in which a controller and at least one memory device are accommodated, and an interface externally exposed from the case and configured to be coupled to a host, where the case includes a plurality of surfaces comprising a first surface and a second surface facing the first surface, a plurality of first structures protruding from the first surface by a first height, and a plurality of second structures protruding from the second surface by a second height.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a server device according to one or more embodiments;

FIGS. 2 and 3 are diagrams illustrating a server module included in a server device according to one or more embodiments;

FIG. 4 is an exploded view illustrating a storage device according to one or more embodiments;

FIGS. 5 and 6 are diagrams illustrating the exterior of a storage device according to one or more embodiments;

FIGS. 7 to 9 are diagrams illustrating storage devices according to one or more embodiments;

FIGS. 10A and 10B are diagrams illustrating the exterior of a storage device according to one or more embodiments;

FIGS. 11A and 11B are diagrams illustrating the exterior of a storage device according to one or more embodiments;

FIGS. 12A and 12B are diagrams illustrating the exterior of a storage device according to one or more embodiments;

FIGS. 13A and 13B are diagrams illustrating the exterior of a storage device according to one or more embodiments;

FIG. 14 is a diagram illustrating the exterior of a storage device according to one or more embodiments;

FIGS. 15 to 17 are diagrams illustrating the exterior of storage devices according to one or more embodiments; and

FIG. 18 is a block diagram illustrating a server device according to according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

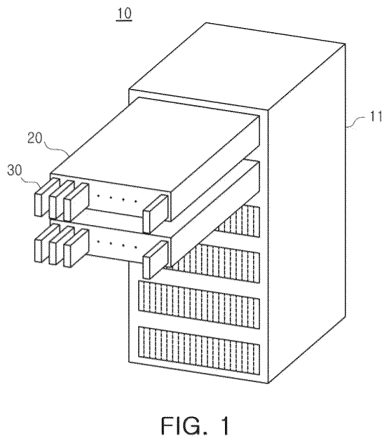

FIG. 1 is a perspective view illustrating a server device according to one or more embodiments.

Referring to FIG. 1, a server device 10 according to one or more embodiments may include a base frame 11 and a plurality of server modules 20 mounted on the base frame 11. Each of the plurality of server modules 20 may be connected to a plurality of storage devices 30. In FIG. 1, it is illustrated that a plurality of storage devices 30 connected to each of the plurality of server modules 20 are arranged in a horizontal direction, but a connection structure of the plurality of storage devices 30 may vary depending on various embodiments.

Each of the plurality of storage devices 30 may be a solid state drive (SSD) device. The plurality of storage devices 30 may store data in response to a command from a processor mounted on each of the plurality of server modules 20, and output the stored data. The server device 10 may operate as a host for each of the plurality of storage devices 30.

While the server device 10 is operating, a large amount of heat may be generated not only by the plurality of server modules 20 but also by the plurality of storage devices 30. In consideration thereof, a data center in which the server device 10 is disposed may include various ways for lowering a temperature of the server device 10 and managing heat generation.

For example, each of the plurality of server modules 20 may include at least one cooling fan for managing heat generation in an air-cooled manner. A cooling fan may be installed in each of the plurality of server modules 20 to intake air from a direction in which the plurality of storage devices 30 are mounted or to discharge air in the direction in which the plurality of storage devices 30 are mounted. An airflow generated by the cooling fan may suppress heat generation generated during the operation of the plurality of storage devices 30, and lower the temperature of the plurality of storage devices 30.

For example, an airflow may be generated in a space between the plurality of storage devices 30 by a cooling fan. A case of each of the plurality of storage devices 30 may be formed of a material having excellent thermal conductivity, such as aluminum, or the like to increase heat dissipation performance. Heat generated during the operation in each of the plurality of storage devices 30 is released through the case, and the efficiency of heat dissipation through the case may be improved through the airflow generated by the cooling fan.

However, when the airflow by the cooling fan is not formed in a region close to a surface of the case of each of the plurality of storage devices 30, the temperature of the plurality of storage devices 30 may increase, resulting in a decrease in performance. For example, when a plurality of storage devices 30 are coupled to a server module 20, a narrow space may be formed between the plurality of storage devices 30. When the cooling fan is turned on and an airflow is formed, the air flowing into the space between the plurality of storage devices 30 may not reach the surface of the case of each of the plurality of storage devices 30.

In one or more embodiments, the cooling performance of each of the plurality of storage devices 30 may be improved by forming a plurality of structures repeatedly disposed on the surface of the case of each of the plurality of storage devices 30. For example, the plurality of structures may have a line shape, a V-shape, a reverse V-shape, or the like. By the plurality of structures, turbulence may be generated in a space close to the surface of the case of each of the plurality of storage devices 30, and cooling performance due to air introduced by the cooling fan may be improved.

The plurality of structures may be provided integrally with the case, unlike a heat sink, or the like, attached to the case of each of the plurality of storage devices 30, and may have a very small thickness of 1 mm or less. For example, a plurality of structures may be provided integrally with the case (i.e., the plurality of structures that are made in a manufacturing process different from that of the case are not physically coupled to the case by separate adhesives). For example, a plurality of structures may be provided integrally with the case by patterning the plurality of structures during the manufacturing operation of the case, or by recessing the remaining portion thereof, excluding the plurality of structures after manufacturing the case. According to one or more embodiments, the storage device 30 may also be understood as having a plurality of recesses formed in the case, other than a plurality of structures.

Therefore, according to one or more embodiments, a plurality of structures may also be formed by performing a process of recessing some regions thereof from the surface of the case to form a plurality of structures. By using the method described above, a plurality of structures that may be implemented for improving cooling performance may be formed without increasing the overall thickness as compared to a conventional case. Accordingly, the cooling performance of the plurality of storage devices 30 and the server device 10 may be improved and the power consumed for cooling may be reduced without reducing the number of storage devices 30 that may be connected to each of the plurality of server modules 20.

In FIG. 1, it is illustrated that the storage device 30 is coupled to the server module 20, but the storage device 30 according to one or more embodiments is not necessarily limited to implementation with the server device 10. For example, the storage device 30 according to one or more embodiments may also be applied to personal computers such as desktop computers, laptop computers, and the like.

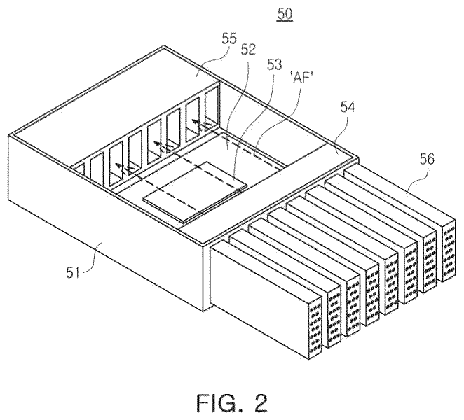

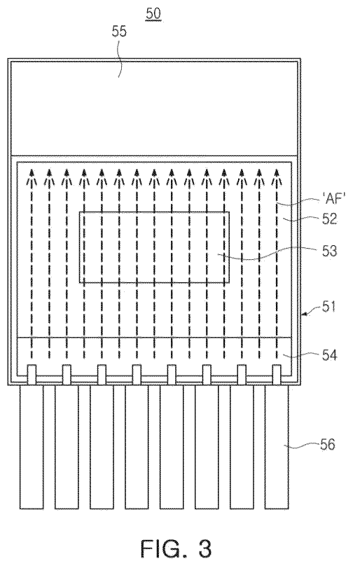

FIGS. 2 and 3 are diagrams illustrating a server module included in a server device according to one or more embodiments.

Referring to FIGS. 2 and 3, a server module 50 according to one or more embodiments may include a housing 51, a server board 52, a processor 53, an interface 54, a cooling fan 55, and the like.

A plurality of storage devices 56 may be coupled to the interface 54, and for example, the interface 54 may be connected to a plurality of storage devices 56 according to standards such as Peripheral Component Interconnect (PCI)-Express, Serial Advanced Technology Attachment (SATA), and Serial Attached Small Computer System Interface (SAS-SCSI)). Through the server board 52 and the interface 54, the processor 53 mounted on the server board 52 may store data in a plurality of storage devices 56 and read data stored in the plurality of storage devices 56. An interface 54 may be provided on one surface of the housing 51 and may be coupled to the plurality of storage devices 56. A cooling fan 55 may be disposed on one surface opposite to the housing 51. The cooling fan 55 includes at least one fan, and may form an airflow AF by intaking air from a space in which a plurality of storage devices 56 are coupled, as shown in FIG. 2, or may form an airflow by discharging air into a space in which a plurality of storage devices 56 are coupled. Therefore, heat generation due to the operation of the server module 50 may be relieved through air cooling.

Air inlets may be provided on rear surfaces of the plurality of storage devices 56, so that an airflow AF generated by the cooling fan 55 may sufficiently cool each component of the plurality of storage devices 56. While the cooling fan 55 is operating, air passing through the interior of each of the plurality of storage devices 56 may be introduced into an internal space of the housing 51, or air passing through the space between the plurality of storage devices 56 may be introduced into the internal space of the housing 51. Heat generation of the server board 52, the processor 53, the interface 54, the plurality of storage devices 56, and the like, may be managed by air cooling by air passing through the internal space of the housing 51 and then being exhausted by the cooling fan 55.

In order to expand the storage capacity of the server module 50, the number of storage devices 56 connected to the interface 54 may be increased. Therefore, as shown in FIGS. 2 and 3, only a very narrow space may be secured between the plurality of storage devices 56 arranged in one direction, and air may not be smoothly introduced through the space between the plurality of storage devices 56. In addition, since the air introduced into the space between the plurality of storage devices 56 does not flow in a space close to the case of each of the plurality of storage devices 56, a temperature of the plurality of storage devices 56 may increase.

An increase in the temperature of the plurality of storage devices 56 may lead to a decrease in the performance of the server module 50 as well as an increase in power consumption. For example, when the increase in temperature of the plurality of storage devices 56 is detected, the processor 53 may increase a rotation speed of a fan included in the cooling fan 55, thereby increasing the power consumption of the server module 50. However, there is a limit to lowering the temperature of the plurality of storage devices 56 by increasing the rotation speed of the fan, and therefore, in one or more embodiments, a plurality of structures may be formed in the case of each of the plurality of storage devices 56 to improve the cooling efficiency of each of the plurality of storage devices 56.

The plurality of structures may have various shapes. For example, each of the plurality of structures may have a line shape extending in one direction, a V-shape, or the like. The plurality of structures may be formed on at least one surface of the case of each of the plurality of storage devices 56 facing another storage device 56. Turbulence may be generated on the surface in which the plurality of structures are formed in addition to laminar flow, and the airflow introduced into the space between the plurality of storage devices 56 due to the turbulence may be formed in a space closer to the surface of the case of each of the plurality of storage devices 56. Accordingly, the cooling efficiency of each of the plurality of storage devices 56 may be improved without increasing the power consumed to drive the cooling fan 55.

Similar to the server module being provided with a cooling fan 55, personal computers such as desktop computers and laptop computers may also include a fan to manage the temperature of components by air cooling. By forming a plurality of structures inducing turbulence in the case of the storage device 56, the cooling efficiency may be improved even when the storage device 56 is while coupled to a personal computer.

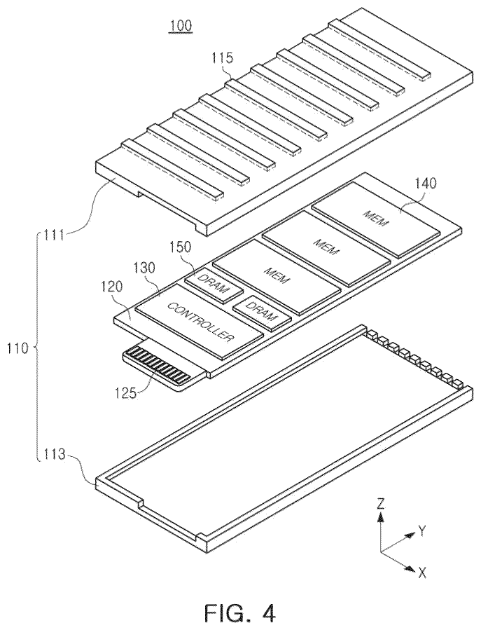

FIG. 4 is an exploded view illustrating a storage device according to one or more embodiments.

Referring to FIG. 4, a storage device 100 according to one or more embodiments may include a case 110, a printed circuit board 120, a controller 130, and a memory device 140. The storage device 100 according to one or more embodiments may have specifications according to various form factors such as 3.5 inches, 2.5 inches, 1.8 inches, M.2, U.2, U.3, Enterprise and Data Center SSD Form Factor (EDSFF), New Form Factor 1 (NF1), and the like. The storage device 100 according to an example embodiment illustrated in FIG. 4 may have a specification according to the EDSFF E1.S form factor.

The case 110 may include an upper case 111 and a lower case 113 that are coupled to each other. A printed circuit board 120 on which a controller 130, a memory device 140, and the like, are mounted may be disposed in a space between the upper case 111 and the lower case 113, and for example, an interface 125 of the printed circuit board 120 may be exposed through an opening formed on one side of the upper case 111 and the lower case 113.

In the storage device 100 according to one or more embodiments, the interface 125 may be exposed through an opening formed on a surface parallel to a short side (side along the X-axis direction) of the upper case 111 and the lower case 113. However, an exposure direction of the interface 125 is not necessarily limited to the form illustrated in FIG. 4. For example, the interface 125 may be exposed through an opening provided on a surface parallel to a long side (side along the Y-axis direction) of the upper case 111 and the lower case 113.

The interface 125 may input/output data according to standards such as PCI-Express, SATA, and SAS, and may be coupled to a server module. A controller 130 and a memory device 140 may be mounted on the printed circuit board 120, and according to an example embodiment, a dynamic random access memory (DRAM) 150 may be mounted on the printed circuit board 120 to improve the performance of the storage device 100. A DRAM 150 may function as a main memory storing data or commands being processed by the controller 130.

A plurality of structures 115 may be formed in at least one of the upper case 111 and the lower case 113. As shown in FIG. 4, the plurality of structures 115 may be structures having a line shape protruding from a surface of the upper case 111 by a predetermined height. The plurality of structures 115 may extend in a direction parallel to the short side of the upper case 111, but the shape of the plurality of structures 115 is not limited thereto. For example, the plurality of structures 115 may extend in a diagonal direction intersecting the direction parallel to the short side and a direction parallel to a long side (Y-axis direction) of the upper case 111. Although the case 110 is illustrated as being non-symmetrical in a rectangular shape, embodiments are not limited thereto, and the case 110 may be symmetrical in a square shape, and the structures 115 may extend in various directions with respect to the various symmetrical sides.

In a state in which the storage device 100 is coupled to the server module, a height of each of the plurality of structures 115 may be 1 mm or less so as not to cause interference with other adjacent storage devices. The plurality of structures 115 may be formed in a process of manufacturing the upper case 111, and thus may be provided integrally with the upper case 111 and may include the same material as that of the upper case 111. In one or more embodiments, a width of each of the plurality of structures 115 defined in the direction of the long side of the upper case 111 may be greater than the height of each of the plurality of structures 115. For example, the width of each of the plurality of structures 115 may be greater than 1 mm.

For example, after forming the upper case 111 through a process such as molding, a plurality of structures 115 may be formed by recessing a portion of the upper case 111 from the surface by a certain depth. By forming a plurality of structures 115 in this manner, a storage device 100 including a plurality of structures 115 may be implemented without increasing thickness as compared to a conventional storage device.

The plurality of structures 115 may function as turbulators which generate turbulence in air flowing in a space adjacent to a surface of the upper case 111 while the storage device 100 is coupled to the server module and operates. For example, turbulence may be generated in a space defined by a plurality of structures 115 and the surface of the upper case 111, and heat dissipation performance through the upper case 111 may be improved to effectively dissipate heat generated by the controller 130, the memory device 140, the DRAM 150, and the like.

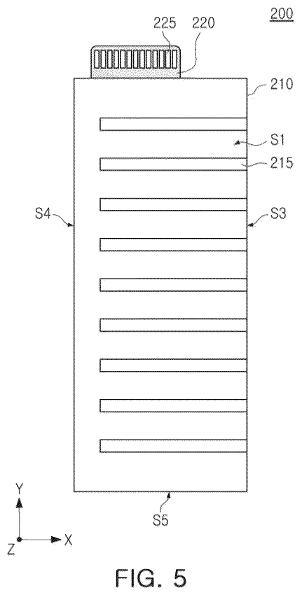

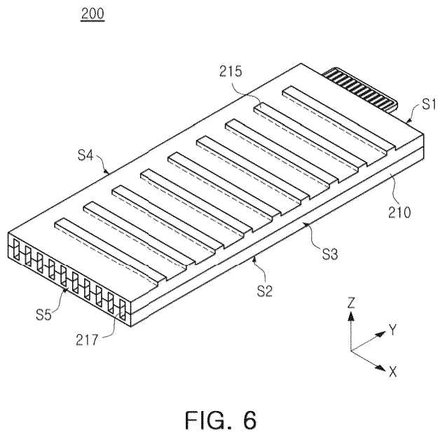

FIGS. 5 and 6 are diagrams illustrating the exterior of a storage device according to one or more embodiments.

Referring to FIGS. 5 and 6, a storage device 200 according to one or more embodiments may include a case 210, an interface 225 externally exposed from the case 210, and the like. The interface 225 may extend from a printed circuit board 220, may be externally exposed from the case 210, and may be coupled to a server module. As described above with reference to FIG. 4, a controller, a memory device, and the like may be mounted on the printed circuit board 220. The controller may receive a command from the server module through an interface 225 and control a memory device in response to the received command.

Referring to FIGS. 5 and 6, the case 210 may include a plurality of surfaces S1 to S5. The first surface S1 and the second surface S2 may face each other, and the third surface S3 and the fourth surface S4 may face each other and may extend from edges of the first surface S1 and the second surface S2. The fifth surface S5 may be disposed on an opposite side of the interface 225, and as shown in FIG. 6, a plurality of air inlets 217 through which air may flow in and out may be formed on the fifth surface S5. Accordingly, when a cooling fan included in the server module is operated while the storage device 200 is mounted on the server module, air may be introduced into an internal space of the case 210 through the air inlets 217, or the air introduced through an opening in which the interface 225 is exposed may be discharged through the air inlets 217.

The case 210 may be formed of a material with excellent thermal conductivity, such as aluminum, so that heat generated by a controller, memory device, and the like, mounted on the printed circuit board 220 may be well dissipated. As illustrated in FIGS. 5 and 6, in the storage device 200 according to one or more embodiments, a plurality of structures 215 may be provided on at least one of the first surface S1 and the second surface S2 of the case 210. By forming a plurality of structures 215 on the first surface S1, turbulence may be generated in an airflow passing through a space close to the first surface S1, and the heat dissipation performance through the first surface S1 may be improved due to the turbulence. The plurality of structures 215 may function as turbulators.

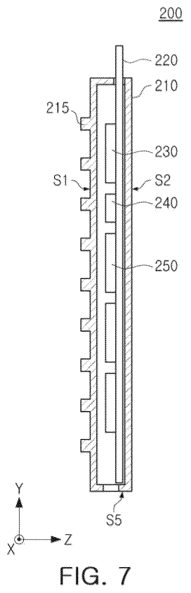

FIGS. 7 to 9 are diagrams illustrating storage devices according to one or more embodiments.

First, referring to FIG. 7, a storage device 200 according to one or more embodiments may include a case 210, a printed circuit board 220 accommodated in an internal space of the case 210, a controller 230, a memory device 250, a DRAM 240, and the like, mounted on the printed circuit board 220. Depending on the example embodiment, the DRAM 240 may not be included in the storage device 200.

Referring to FIG. 7, a plurality of structures 215 may be formed on a first surface S1 of the case 210. The first surface S1 may be a surface having the largest surface area together with a second surface S2 among the surfaces of the case 210. As illustrated in FIG. 7, each of the plurality of structures 215 may be a line structure extending in a direction parallel to a short side (X-axis direction) of the first surface S1 and perpendicular to a long side (Y-axis direction) of the first surface S1. The plurality of structures 215 may be arranged in a direction parallel to the long side of the first surface S1.

As illustrated in FIG. 7, a plurality of structures 215 may be formed integrally with a case 210. The case 210 may be formed of a material having excellent heat dissipation properties, such as aluminum, so that heat generated by a controller 230, a DRAM 240, a memory device 250, and the like, stored in an internal space of the case may be efficiently dissipated. The plurality of structures 215 may be manufactured separately and not attached to the case 210, but may be formed during the manufacturing process of the case 210. For example, assuming that the case 210 is manufactured by a molding process or the like, a structure for forming a plurality of structures 215 may be reflected in a frame of a molding process. Alternatively, after manufacturing the case 210, the plurality of structures 215 may be formed integrally with the case 210 by recessing the remaining region except for the plurality of structures 215 on the first surface S1.

In a direction perpendicular to the first surface S1 (Z-axis direction), a height of each of the plurality of structures 215 may be 1 mm or less and 0.2 mm or more. This height may reduce interference with other storage devices while the storage device 200 is coupled to the server module, and may cause turbulence in the air passing around the storage device 200. A width of each of the plurality of structures 215 defined in a direction parallel to the long side of the first surface S1 may be 1 mm or more, and the width of each of the plurality of structures 215 may be greater than the height. However, embodiments are not limited thereto, and the dimensions of each of the plurality of structures 215 are not necessarily limited to such a form.

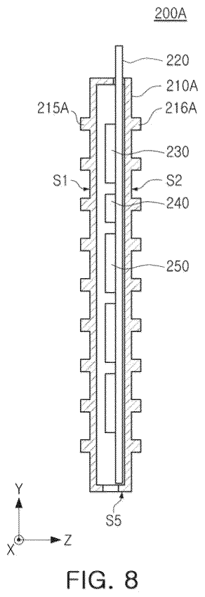

Next, referring to FIG. 8, a plurality of first structures 215A protruding from a surface of the first surface S1 by a first height may be formed on the first surface S1 of the case 210A of the storage device 200A, and a plurality of second structures 216A protruding from a surface of the second surface S2 by a second height may be formed on the second surface S2 of the case 210A thereof. The first height and the second height may be equal to or different from each other. In an example embodiment illustrated in FIG. 8, each of the plurality of first structures 215A and the plurality of second structures 216A may be a line structure extending in a direction parallel to the short side of the first surface S1.

Referring to FIG. 8, the plurality of first structures 215A and the plurality of second structures 216A may be formed integrally with the case 210A, and thus may include the same material as that of the case 210A. In addition, the plurality of first structures 215A formed on the first surface S1 and the plurality of second structures 216A formed on the second surface S2 may be disposed at the same position in the direction of the long side of the first surface S1. That is, the structures 215A may have a one-to-one correspondence with a corresponding location of structures 216A, resulting in the symmetrical cross-sectional view of FIG. 8. Accordingly, as illustrated in FIG. 8, the plurality of first structures 215A and the plurality of second structures 216A may be matched one to one and disposed.

However, embodiments are not limited thereto, and a position in which the plurality of first structures 215A are disposed may be different from a position in which the plurality of second structures 216A are disposed in the direction of the long side of the first surface S1. For example, in the direction of the long side of the first surface S1, the plurality of first structures 215A and the plurality of second structures 216A may be disposed alternately.

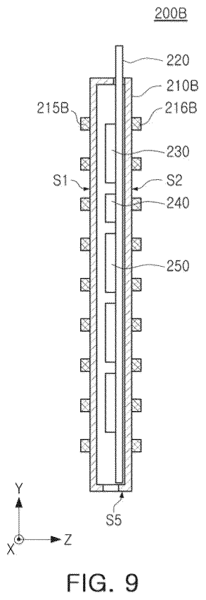

In a storage device 200B illustrated in FIG. 9, a plurality of first structures 215B may be formed on a first surface S1 of a case 210B, and a plurality of second structures 216B may be formed on a second surface S2 of the case 210B. Each of the plurality of first structures 215B and the plurality of second structures 216B may be a line structure extending in a direction parallel to the short side of the first surface S1.

In FIG. 9, the plurality of first structures 215B and the plurality of second structures 216B may be formed separately from the case 210B. For example, when a manufacturing process of the case 210B is completed, a plurality of first structures 215B and a plurality of second structures 216B may not be present on the first surface S1 and the second surface S2 of the case 210B. A plurality of first structures 215B and a plurality of second structures 216B may be manufactured in a separate process from the manufacturing process of the case 210B and then attached to each of the first surface S1 and the second surface S2.

Materials of the plurality of first structures 215B and the plurality of second structures 216B may be variously selected. In one or more embodiments, each of the plurality of first structures 215B and the plurality of second structures 216B may be formed of the same material as that of the case 210B, for example, aluminum. In one or more embodiments, each of the plurality of first structures 215B and the plurality of second structures 216B may be formed of a material different from the case 210B, such as plastic. According to one or more embodiments, a portion of the plurality of first structures 215B and the plurality of second structures 216B may be formed of the same material as that of the case 210B, and others may be formed of a material different from that of the case 210B.

In FIG. 9, the contents described above with reference to FIGS. 7 and 8 may be applied. For example, the plurality of first structures 215B and the plurality of second structures 216B may be arranged in the same position in a direction parallel to the long side of the first surface S1, or may be arranged in different positions in a direction parallel to the long side of the first surface S1. In addition, in each of the plurality of first structures 215B and the plurality of second structures 216B, the width may be greater than the height, and the height may be 1 mm or less.

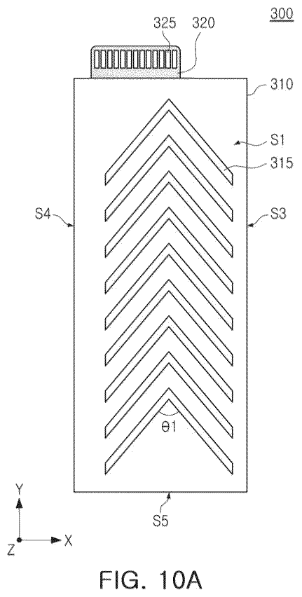

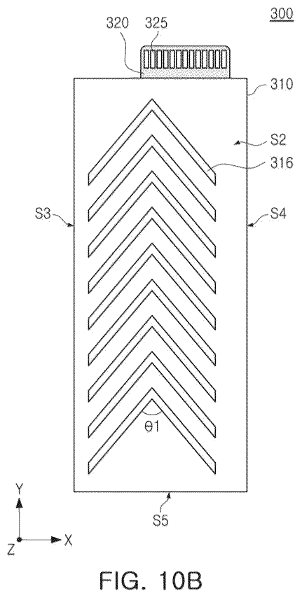

FIGS. 10A and 10B are diagrams illustrating the exterior of a storage device according to one or more embodiments.

Referring to FIGS. 10A and 10B, a storage device 300 may include a case 310, a printed circuit board 320 accommodated inside the case 310, and the like, and the printed circuit board 320 may include an interface 325 externally exposed from the case 310. A controller, a memory device, and the like may be mounted on the printed circuit board 320.

In FIGS. 10A and 10B, the case 310 may include a plurality of surfaces S1 to S5, and a plurality of structures 315 and 316 may be formed on each of the first surface S1 and the second surface S2, which occupy a large area among the plurality of surfaces S1 to S5. A plurality of first structures 315 may be formed on the first surface S1, and a plurality of second structures 316 may be formed on the second surface S2.

Each of the plurality of structures 315 and 316 may have a V-shape. Referring to FIGS. 10A and 10B, each of the plurality of structures 315 and 316 may have a V-shape included in the case 310, where the V-shapes point in a direction away from a fifth surface S5. The direction in which the V-shape faces/points may be parallel to the long side of the first surface S1.

Referring to FIG. 10A, each of the plurality of first structures 315 may include a first diagonal line structure extending in a first diagonal direction intersecting the directions parallel to short side and the long side of the first surface S1, and a second diagonal line structure extending in a second diagonal direction different from the first diagonal direction. An angle between the first diagonal line structure and the second diagonal line structure may be a first angle θ1. The first angle θ1 may be an acute angle, and in one or more embodiments, the first angle θ1 may be an angle greater than or equal to 30 degrees. For example, the first angle θ1 may be 45 degrees.

Referring to FIGS. 10A and 10B, respectively, a position in which the plurality of first structures 315 are disposed on the first surface S1 may correspond to a position in which the plurality of second structures 316 are disposed on the second surface S2. Accordingly, a region in which the plurality of first structures 315 are disposed on the first surface S1 may face a region in which the plurality of second structures 316 are disposed on the second surface S2.

However, the position in which the plurality of first structures 315 are disposed on the first surface S1 may be different from the position in which the plurality of second structures 316 are disposed on the second surface S2. For example, the region in which the plurality of first structures 315 are disposed on the first surface S1 may be offset in the direction parallel to the short side and/or the direction parallel the long side of the first surface S1 from the region in which the plurality of second structures 316 are disposed on the second surface S2. In one or more embodiments, the plurality of first structures 315 may be disposed closer to the third surface S3 than to the fourth surface S4 on the first surface S1, and the plurality of second structures 316 may be disposed closer to the fourth surface S4 than to the third surface S3 on the second surface S2. In addition, the plurality of structures 315 and 316 may be formed integrally with the case 310, or may be manufactured in a separate process different from the manufacturing process of the case 310 and then attached to the first surface S1 and the second surface S2.

The structures 315 and 316 having the V-shape described with reference to FIGS. 10A and 10B may also be applied to the storage device 200 as described with reference to FIGS. 5 and 6 above. In this case, the structures having the V-shape may be provided on the first surface S1 of the case 210 included in the storage device 200.

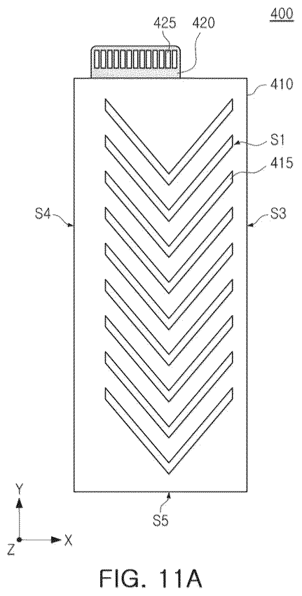

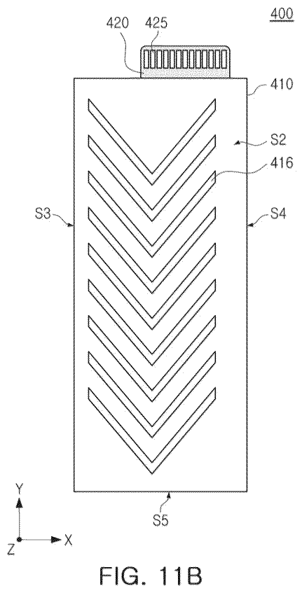

FIGS. 11A and 11B are diagrams illustrating the exterior of a storage device according to one or more embodiments.

Referring to FIGS. 11A and 11B, a storage device 400 may include a case 410, a printed circuit board 420 accommodated inside the case 410, and the like, and an interface 425 of the printed circuit board 420 may be externally exposed from the case 410. A controller, a memory device, and the like may be mounted on the printed circuit board 420.

The case 410 may include a plurality of surfaces S1 to S5, and a plurality of structures 415 and 416 may be formed on each of a first surface S1 and a second surface S2, which occupy a large area among the plurality of surfaces S1 to S5. A plurality of first structures 415 may be formed on the first surface S1, and a plurality of second structures 416 may be formed on the second surface S2.

Each of the plurality of structures 415 and 416 may have a V-shape, similar to that described with reference to FIGS. 10A and 10B above. Unlike the example embodiment of FIGS. 10A and 10B in which each of the plurality of structures 315 and 316 has a V-shape facing/pointing to the interface 325, in FIGS. 11A and 11B, each of the plurality of structures 415 and 416 may have a V-shape facing/pointing to the fifth surface S5 of the case 410. Each of the plurality of structures 415 and 416 may include a first diagonal line structure extending in a first diagonal direction intersecting the direction parallel to short side and the direction parallel to the long side of the first surface S1, and a second diagonal line structure extending in a second diagonal direction different from the first diagonal direction. An angle between the first diagonal line structure and the second diagonal line structure may be an acute angle, for example, 45 degrees.

Referring to FIGS. 11A and 11B, a position in which the plurality of first structures 415 are disposed on the first surface S1 may correspond to a position in which the plurality of second structures 416 are disposed on the second surface S2. However, the position in which the plurality of first structures 415 are disposed on the first surface S1 may be different from the position in which the plurality of second structures 416 are disposed on the second surface S2. In addition, the plurality of structures 415 and 416 may be formed integrally with the case 410, or may be manufactured in a separate process from the manufacturing process of the case 410 and then attached to the first surface S1 and the second surface S2.

The structures 415 and 416 having the V-shape described with reference to FIGS. 11A and 11B may also be applied to the storage device 200 described with reference to FIGS. 5 and 6 above. In this case, the structures having the V-shape facing the fifth surface S5 may be provided on the first surface S1 of the case 210 included in the storage device 200.

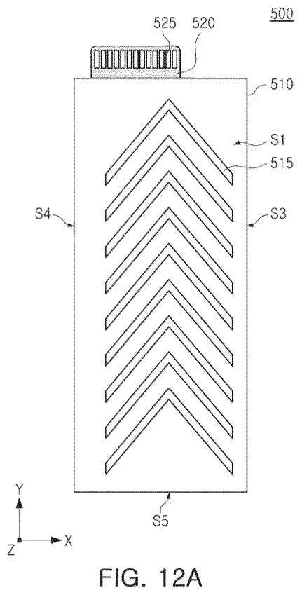

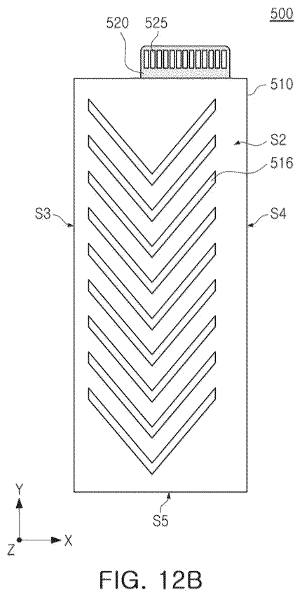

FIGS. 12A and 12B are diagrams illustrating the exterior of a storage device according to one or more embodiments.

Referring to FIGS. 12A and 12B, a storage device 500 may include a case 510, a printed circuit board 520 accommodated inside the case 510, and the like. A controller, a memory device, and the like may be mounted on the printed circuit board 520, and an interface 525 of the printed circuit board 520 may be externally exposed from the case 510.

The case 510 may include a plurality of surfaces S1 to S5, and a plurality of structures 515 and 516 may be formed on each of the first surface S1 and the second surface S2. A plurality of first structures 515 may be formed on the first surface S1, and a plurality of second structures 516 may be formed on the second surface S2.

The plurality of first structures 515 may have a V-shape facing/pointing in a direction in which the interface 525 is exposed, similar to that described above with reference to FIG. 10A. The plurality of second structures 516 may have a V-shape facing/pointing toward the fifth surface S5 similar to that described above with reference to FIG. 11B.

Each of the plurality of structures 515 and 516 may include a first diagonal line structure extending in a first diagonal direction intersecting the direction parallel to short side and the direction parallel to the long side of the first surface S1, and a second diagonal line structure extending in a second diagonal direction different from the first diagonal direction. An angle between the first diagonal line structure and the second diagonal line structure may be an acute angle. The plurality of structures 515 and 516 may be formed integrally with the case 510, or may be manufactured in a separate process different from the manufacturing process of the case 510 and then attached to the first surface S1 and the second surface S2.

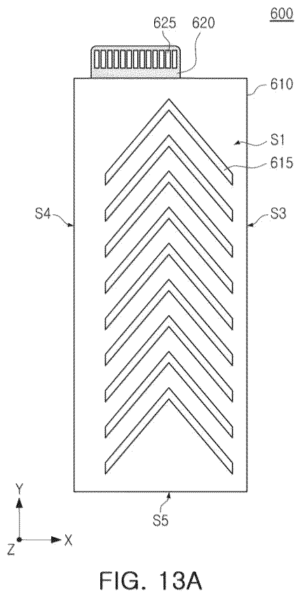

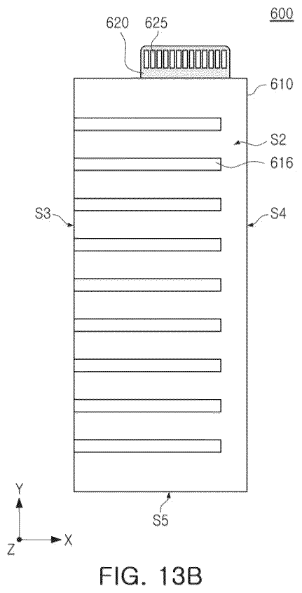

FIGS. 13A and 13B are diagrams illustrating the exterior of a storage device according to one or more embodiments.

Referring to FIGS. 13A and 13B, a storage device 600 may include a case 610, a printed circuit board 620 accommodated inside the case 610, and the like. A controller, a memory device, and the like may be mounted on the printed circuit board 620, and an interface 625 of the printed circuit board 620 may be externally exposed from the case 610.

The case 610 may include a plurality of surfaces S1 to S5, and a plurality of structures 615 and 616 may be formed on each of the first surface S1 and the second surface S2. The plurality of first structures 615 formed on the first surface S1 may have a V-shape facing/pointing in a direction in which the interface 625 is exposed, similar to that described above with reference to FIG. 10A. The plurality of second structures 616 formed on the second surface S2 may have a line shape extending in a direction parallel to the short side of the second surface S2 (X-axis direction), similar to that described above with reference to FIGS. 5 and 6. The plurality of structures 615 and 616 may be formed integrally with the case 610, or may be manufactured in a separate process from the manufacturing process of the case 610 and then attached to the first surface S1 and the second surface S2.

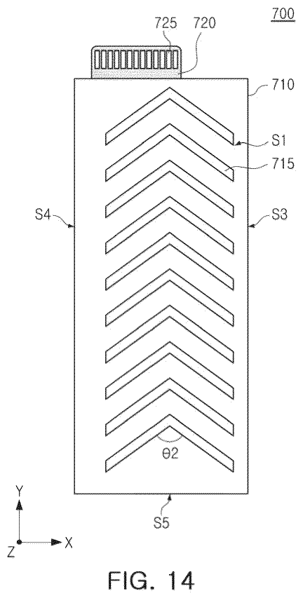

FIG. 14 is a diagram illustrating the exterior of a storage device according to one or more embodiments.

A storage device 700 illustrated in FIG. 14 may include a case 710, a printed circuit board 720 accommodated inside the case 710, and the like. An interface 725 of the printed circuit board 720 may be externally exposed from the case 710 to be coupled to a server module, a personal computer, and the like, and a controller, a memory device, and the like, may be mounted on the printed circuit board 720.

The case 710 may include a plurality of surfaces, and a plurality of structures 715 may be formed on a first surface S1. According to one or more embodiments, a plurality of structures may also be formed on a second surface disposed opposite to the first surface S1. The plurality of structures 715 formed on the first surface S1 may have a V-shape facing/pointing in a direction in which the interface 725 is exposed, similar to that described above with reference to FIG. 10A. A V-shape may be formed by a first diagonal line structure extending in a first diagonal direction and a second diagonal line structure extending in a second diagonal direction.

In FIG. 14, an angle between the first diagonal line structure and the second diagonal line structure may be an acute second angle θ2. The second angle θ2 may be greater than the first angle θ1 described with reference to FIGS. 10A and 10B above, and may be, for example, 60 degrees. As described above, a size of the angle in each of the plurality of structures 715 having a V-shape may be selected as various angles as needed.

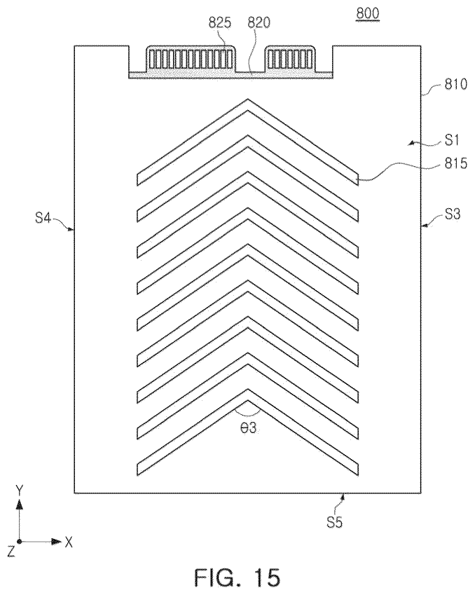

FIGS. 15 to 17 are diagrams illustrating the exterior of storage devices according to one or more embodiments.

Storage devices 800, 800A, and 800B may have specifications according to form factors such as 3.5 inches, 2.5 inches, U.2, and the like. First, referring to FIG. 15, the storage device 800 may include a case 810, a printed circuit board 820 accommodated inside the case 810, and the like. An interface 825 of the printed circuit board 820 may be provided externally from the case 810 and may be coupled to a server module, a personal computer, and the like, and a controller, a memory device, and the like, may be mounted on the printed circuit board 820. For example, the shape of the interface 825 may be determined according to a SATA interface, a PCI-Express interface, and the like, for the storage device 800 to communicate with an external host.

The case 810 may include a plurality of surfaces, and a plurality of structures 815 may be formed on a first surface S1. A plurality of structures 815 formed on the first surface S1 may have a V-shape facing/pointing in a direction in which the interface 825 is exposed. A V-shape may be formed by a first diagonal line structure extending in a first diagonal direction and a second diagonal line structure extending in a second diagonal direction.

An angle between the first diagonal line structure and the second diagonal line structure may be an acute third angle θ3. The third angle θ3 may be greater than the first angle θ1 and the second angle θ2 according to embodiments described above. This may be because an area of the first surface S1 included in the storage device 800 is greater than the area of the first surface S1 included in the storage devices 100 to 700 according to other embodiments described above.

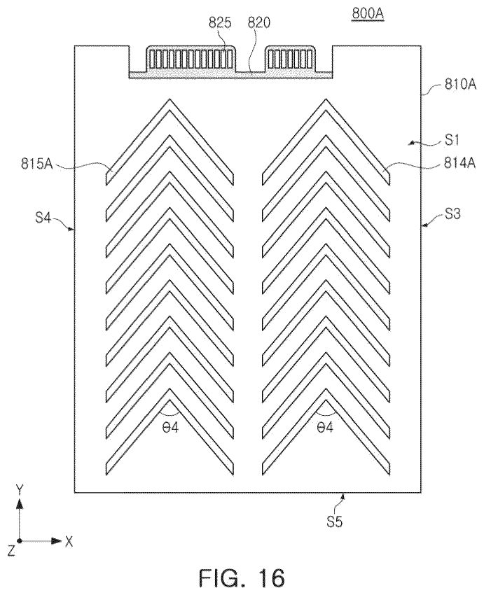

In FIG. 16, a plurality of structures 814A and 815A may be formed on a first surface S1 of a storage device 800A in a direction parallel to a short side of the first surface S1. Accordingly, the plurality of structures 814A and 815A may be arranged in directions parallel to the short side or the long side of the first surface S1. The plurality of first substructures 814A may be disposed closer to the third surface S3 than the fourth surface S4, and the plurality of second substructures 815A may be disposed closer to the fourth surface S4 than the third surface S3. Therefore, as compared to the example embodiment described with reference to FIG. 15, an angle in each of the V-shaped structures 814A and 815A may be formed as a fourth angle θ4, smaller than the third angle θ3.

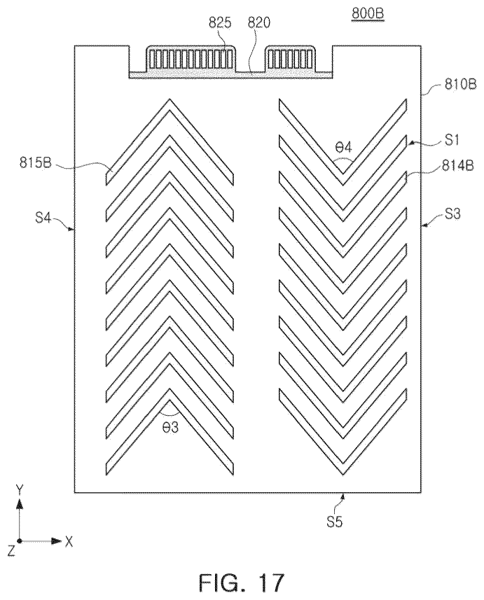

Referring to FIG. 17, a plurality of structures 814B and 815B may be formed on a first surface S1 of a storage device 800Bb in a direction parallel to a short side of the first surface S1, and the plurality of structures 814B and 815B may have a V-shape facing/pointing in different directions. For example, each of the plurality of first substructures 814B disposed closer to the third surface S3 than the fourth surface S4 may have a V-shape facing/pointing toward the interface 825, and each of the plurality of second substructures 815B disposed closer to the fourth surface S4 than the third surface S3 may have a V-shape facing the fifth surface S5. The plurality of first substructures 814B or the plurality of second substructures 815B may have a line shape.

Angles in each of the structures 814B and 815B having V-shapes may be formed as a fourth angle θ4. However, according to one or more embodiments, in the storage device 800A and 800B as illustrated in FIGS. 16 and 17, the angles in each of the plurality of first substructures 814A and 814B may be different from the angles in each of each of the plurality of second substructures 815A and 815B.

In the example embodiments shown in FIGS. 15-17, similar structures may be disposed on the second surface S2. That is, a plurality of structures may be formed integrally with the second surface S2 or attached to the second surface S2. The plurality of structures on the second surface S2 may correspond to the locations of the plurality of structures on the first surface S1. The plurality of structures on the second surface S2 may include the same shapes (e.g., line shapes, V-shapes, etc.) as the plurality of structures on the first surface S1, or may vary according to one or more embodiments. That is, the structures shown in all figures may be variously combined to effectuate heat dissipation.

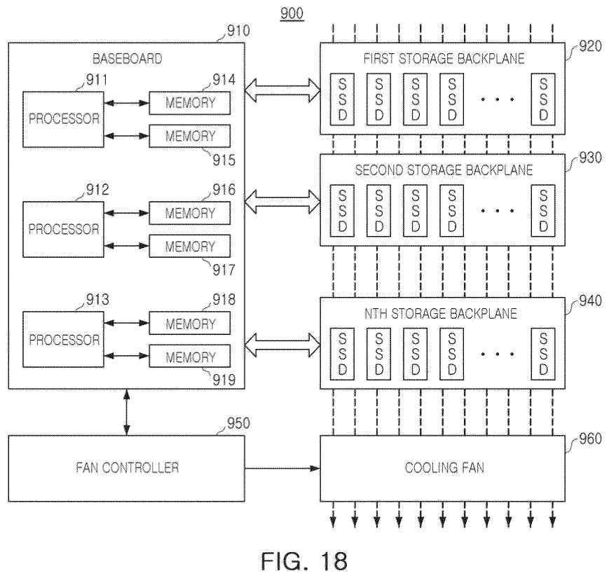

FIG. 18 is a block diagram illustrating a server device according to according to one or more embodiments.

Referring to FIG. 18, a server device 900 may include a baseboard 910, a plurality of storage backplanes 920, 930, and 940, a fan controller 950, and a cooling fan 960. A plurality of processors 911 to 913 and a plurality of memories 914 to 919 may be mounted on the baseboard 910. Each of the plurality of processors 911 to 913 may be a central processing unit (CPU), a system on chip (SOC), or the like, and each of the plurality of memories 914 to 919 may be a DRAM.

Each of storage backplanes 920, 930, and 940 includes a plurality of storage devices (SSDs), and the baseboard 910 may be connected to the storage backplanes 920, 930, and 940 via one of the various interfaces described above. For example, the baseboard 910 may be coupled to storage devices (SSDs) of each of the storage backplanes 920, 930, and 940 via interfaces such as PCI-Express, SATA, SAS, or the like. The processors 911 to 913 may control storage devices (SSDs) to store data or read data stored in the storage devices (SSDs).

During the operation of the server device 900, significant amounts of heat may be generated, and heat may cause the temperature of the processors 911 to 913, memories 914 to 919, and storage devices (SSD) to increase, resulting in reduced performance. For example, during the operation of the server device (900), the temperature of the components included in each of the storage devices (SSD) may increase to 80 degrees Celsius or more. To manage such heat generation, the server device 900 may include a cooling fan 960 for cooling the heat generation of storage devices (SSD) by air cooling. The operation of the cooling fan 960, for example, the rotation speed of the cooling fan 960 may be controlled by a fan controller 950, and the fan controller 950 may be controlled by at least one of the processors 911 to 913.

For example, the server device 900 may further include a temperature sensor for detecting the temperature of each component. If the temperature of the storage backplanes 920, 930, and 940 is determined to be increasing, the fan controller 950 may increase a rotation speed of the cooling fan 960. Accordingly, the airflow moving from the space in which the storage devices (SSD) are installed to the cooling fan 960 may be accelerated, and the temperature of the storage devices (SSD) may be lowered.

However, increasing the rotation speed of the cooling fan 960 may have limitations in lowering the temperature of the storage devices (SSD). In one or more embodiments, a plurality of structures may be formed on at least one of the surfaces included in the case of each of the storage devices (SSD). Turbulence may be generated on the surface in which a plurality of structures are formed, and thus the cooling efficiency of the cooling fan 960 for lowering the temperature of the storage devices (SSD) by air cooling may be improved.

As set forth above, according to one or more embodiments, a plurality of structures that function as a turbulator to generate a vortex in air flowing around a case may be provided in the case of the storage device. Therefore, in a state in which the storage device is mounted on a server, the heat dissipation performance of the storage device may be improved by generating a vortex in the air flowing around the case of the storage device, and the power consumption of the server may be reduced.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A storage device comprising:
a printed circuit board comprising an interface configured to be coupled to an external host;
a controller on the printed circuit board;
at least one memory device on the printed circuit board, and configured to store data in response to control of the controller; and
a case having an internal space accommodating the printed circuit board, the controller, and the at least one memory device and externally exposing the interface,
wherein the case comprises:
a first surface and a second surface facing each other,
a third surface and a fourth surface facing each other and extending from edges of the first surface and the second surface, and
a plurality of structures on at least one of the first surface and the second surface, the plurality of structures being configured to generate air turbulence.

2. The storage device of claim 1, wherein the first surface comprises a first side of a first length and a second side of a second length that is longer than the first length, and
wherein each of the plurality of structures comprises a line structure extending in a direction parallel to the first side of the first surface and perpendicular to the second side of the first surface.

3. The storage device of claim 1, wherein each of the plurality of structures has a V-shape comprising a first diagonal line structure and a second diagonal line structure intersecting the first diagonal line structure.

4. The storage device of claim 3, wherein an angle between the first diagonal line structure and the second diagonal line structure is an acute angle.

5. The storage device of claim 4, wherein the acute angle is at least 30 degrees.

6. The storage device of claim 3, wherein the case further comprises a fifth surface connected to each of the first surface, the second surface, the third surface, and the fourth surface, and
wherein the V-shape of each of the plurality of structures points in a direction away from the fifth surface.

7. The storage device of claim 3, wherein the case further comprises a fifth surface extending from edges of the first surface, the second surface, the third surface, and the fourth surface, and
wherein the V-shape of each of the plurality of structures points in a direction toward the fifth surface.

8. The storage device of claim 1, wherein a height of each of the plurality of structures is in a range of 0.2 mm to 1 mm.

9. The storage device of claim 1, wherein the plurality of structures comprise a material that is the same as a material of the first surface and the second surface, and
wherein the plurality of structures are integral with at least one of the first surface and the second surface.

10. The storage device of claim 1, wherein the plurality of structures comprise a material that is different from a material of the first surface and the second surface.

11. The storage device of claim 1, wherein the case further comprises a fifth surface extending from edges of the first surface, the second surface, the third surface, and the fourth surface, and
wherein the fifth surface comprises a plurality of air inlets configured to introduce air into the case.

12. The storage device of claim 1, wherein the plurality of structures comprise a plurality of first substructures that are closer to the third surface than the fourth surface, and a plurality of second substructures that are closer to the fourth surface than the third surface.

13. The storage device of claim 12, wherein the plurality of first substructures and the plurality of second substructures have a same shape.

14. The storage device of claim 12, wherein the plurality of first substructures and the plurality of second substructures have different shapes.

15. A storage device comprising:
a printed circuit board comprising an upper surface on which a controller and at least one memory device are provided, and an interface configured to be coupled to a host; and
a case having an internal space accommodating the printed circuit board, the case comprising a first surface and a second surface that are parallel to the upper surface of the printed circuit board,
wherein at least one of the first surface and the second surface comprises a plurality of turbulators.

16. The storage device of claim 15, wherein each of the plurality of turbulators is integral with the case.

17. The storage device of claim 15, wherein the first surface comprises a first side of a first length and a second side of a second length that is longer than the first length, and
wherein each of the plurality of turbulators extends in a direction intersecting the second side of the first surface.

18. The storage device of claim 15, wherein the plurality of turbulators comprise a plurality of first turbulators on the first surface and a plurality of second turbulators formed on the second surface, and
wherein a region in which the plurality of first turbulators are on the first surface faces a region in which the plurality of second turbulators are on the second surface.

19. The storage device of claim 15, wherein the first surface comprises a first side of a first length and a second side of a second length that is longer than the first length,
wherein the plurality of turbulators comprise a plurality of first turbulators on the first surface and a plurality of second turbulators on the second surface,
wherein the case further comprises a third surface and a fourth surface facing each other and extending from edges of the first surface and the second surface in a direction parallel to the second side of the first surface, and
wherein the plurality of first turbulators are closer to the third surface than to the fourth surface on the first surface, and the plurality of second turbulators are closer to the fourth surface than to the third surface on the second surface.

20. A storage device, comprising:
a case having an internal space in which a controller and at least one memory device are accommodated; and
an interface externally exposed from the case and configured to be coupled to a host,
wherein the case further comprises:
a plurality of surfaces comprising a first surface and a second surface facing each other;
a plurality of first structures protruding from the first surface by a first height; and
a plurality of second structures protruding from the second surface by a second height.
